(19) United States
(12) Patent Application Publication
(10) Pub. No.: US 2018/0196163 A1
(43) Pub. Date: Jul. 12, 2018

(54) STAND ALONE SYSTEM FOR DETERMINING THE LOCATIONS OF LIGHTNING STRIKES

(71) Applicant: John P. Desmond, Lake Oswego, OR (US)

(72) Inventor: John P. Desmond, Lake Oswego, OR (US)

(21) Appl. No.: 15/845,838

(22) Filed: Dec. 18, 2017

Related U.S. Application Data
(60) Provisional application No. 62/443,578, filed on Jan. 6, 2017.

(51) Int. Cl. G01W 1/16; G01R 33/10

(52) U.S. Cl. CPC G01W 1/16; G01R 33/10

(57) ABSTRACT

A stand-alone method, system, and apparatus for monitoring electromagnetic signals generated by lightning events, and determining the source of the electromagnetic signals, as well as the bearing and distance between the lightning event and the electromagnetic signal detection unit. This invention improves on previous methods and devices by employing techniques to better determine the type of electromagnetic sources detected by the device, the bearing to the source and the distance to the source. The invention incorporates a means to establish the density of lightning events within a certain area, to indicate this density and to inform the direction of movement of the occurrences. The invention also provides a means to network any number of these devices thereby improving the accuracy of all networked devices.

### CROSS-REFERENCE TO RELATED APPLICATION

This Application claims priority to Provisional Application No. 62443578, filed on Jan. 6, 2017, entitled “Method and Apparatus for Determining the Location of an Electromagnetic Source”, the entire contents of which are incorporated herein by reference.

### BACKGROUND

Knowing the precise locations of lightning strikes can be important, as knowing the positions of lightning storms can allow individuals to avoid dangerous situations both at sea and on land. Unfortunately, the only current systems that are able to reliably determine the positions of lightning strikes require large investments in infrastructure (e.g., multiple antennas distributed across a wide area, high definition cameras on orbiting satellites). Due to the high cost of implementing such infrastructure, individuals who want to acquire precise lightning strike location information must purchase and/or stream it from large weather service providers. However, because of the limitations of data transfer individuals are not able to stream information at all locations. This leaves individuals in remote locations in a dangerous position. For example, when at sea, if a fishing vessel is not able to acquire a reliable signal from a weather service provider they become blind to approaching thunder storms. Additionally, current systems are unable to provide information on cloud to cloud lightning strikes, which can begin up to 30 minutes before the occurrence of cloud to ground strikes.

Moreover, current standalone systems are unable to accurately determine lightning strike position because they estimate the position of lightning strikes using the amplitude of a detected electromagnetic signal. That is, current standalone systems are unable to precisely determine the distance of a lightning strike alone because (based on signal amplitude decreasing as it travels) they determine the location of a lightning strike by directly correlating the distance that the signal has traveled with the amplitude of the signal. However, because the amplitude of signals emitted by lightning strike varies according to the strength of the corresponding strike, and because current standalone systems are unable to determine the strength of individual lightning strikes, current standalone systems estimate small strikes (that emit low amplitude signals) to be farther away than they actually are, and while estimating that large strikes (that emit high amplitude signals) are closer than they actually are.

### BRIEF DESCRIPTION OF THE DRAWINGS

The detailed description is described with reference to the accompanying figures. In the figures, the left-most digit(s) of a reference number identifies the figure in which the reference number first appears. The same reference numbers in different figures indicate similar or identical items.

FIG. 1 is a schematic diagram of an illustrative environment for determining the location of lightning strikes.

FIG. 2 is a block diagram of an illustrative computing architecture for determining the positions of lightning strikes.

FIG. 3 is a flow diagram of an illustrative process to determine the location of lightning events.

FIG. 4 is a flow diagram of an illustrative process for transforming EM signals detected by the EM signal detection unit into computer data to facilitate presentation in a user interface.

FIG. 5 is a schematic diagram that illustrates the operation of an electromagnetic signal detection unit and a display showing signal information.

### DETAILED DESCRIPTION

This disclosure is generally directed to a stand-alone method, system, and apparatus for determining the locations of lightning strikes. The disclosed method, system, and apparatus use the effects of the atmosphere, ionosphere, and earth's magnetic field on electromagnetic signals generated by lightning strikes (EM signals) to significantly improve performance over previous systems without requiring multiple sensors, GPS, a central processing site, or an information distribution network.

In some embodiments, the disclosed system may include antennas for monitoring electromagnetic (EM) fields and detecting electromagnetic (EM) events (e.g., lightning strikes), one or more modules and/or circuitry for amplifying, filtering, and processing EM events, and a means to display, store and output the type and location of an EM event. The antennas may include a vertical antenna configured to continuously detect electric fields, and two circular or loop antennas are configured to detect magnetic fields. The vertical antenna and the two circular or loop antennas may all be components of a single apparatus, may be components of separate apparatuses, or a combination thereof.

In some embodiments, electric and magnetic signals that are received by the antennas may be amplified, filtered, and/or converted to digital data. The system may then perform signal analysis and data processing on the digital data to determine the source of the received signal (i.e., whether the received signal corresponds to an EM signal from a lightning event), the bearing of the received signal, the distance to the source of the signal, or a combination thereof.

In some embodiments, the system may model the dispersion patterns that an EM signal is expected to possess at different distances of propagation (e.g., every 100 km). The system may model these expected dispersion patterns using the physical properties of EM signals, the ionosphere, the earth, the atmosphere, or a combination thereof. For example, once a lightning strike occurs, the earth and the ionosphere act as a waveguide that guides the EM signal, restricting the loss of energy from three dimensions to two dimensions. As the EM signal propagates away from the location of the lightning strike, the EM signal is affected by the atmosphere and ionosphere in predictable ways. That is, as the EM signal propagates, the earth and the ionosphere act as a waveguide wherein EM signal continuously reflects between the earth and ionosphere are it travels, with each of the reflections generating dispersion effects that modify the EM signal.

Because different frequencies are reflected at knowable angles, and because the frequencies present in an EM signal are known, the system disclosed herein may calculate the dispersion patterns that can be expected to be present in an EM signal as it propagates. That is, because the dispersion induced by reflections off the ionosphere and the earth are calculable, the system disclosed herein may determine the dispersion pattern that an EM signal would be expected to have at different distances (e.g., every 5 km). In other words, the system may model what an EM signal would be expected to look like at different distances of travel from the location of the lightning strike.

In some embodiments, the disclosed system may determine the distance that an EM signal has traveled (i.e., the distance to the location of the strike) based on the dispersion pattern it exhibits. The disclosed system may employ enhanced digital signal processing, probabilistic methods, most likely estimate (MLE) algorithms, or a combination thereof to match the dispersion pattern of the EM signal to a modeled dispersion pattern for a corresponding distance. In this way, by determining the dispersion pattern that the EM signal most closely resembles, the system is able to determine the distance between the antenna and the location of the lightning strike.

In some embodiments, the disclosed system determines the bearing of an EM signal by comparing the signal level from the circular or loop antennas. The disclosed system may determine the bearing of the EM signal using the strength of the signal, the phase relations between the electronic and magnetic components of the signal, the polarization of the signal (e.g., phase relationships between the polarization of electric components of the signal to magnetic components of the signal, phase relationships between the polarization between the magnetic components of the signal, etc.) or a combination thereof. The disclosed system may then determine the location of the lightning strike corresponding to the EM signal using the determined bearing and the distance.

This information may then be presented to a user via a visual display, an audible output, or a combination thereof. For example, the disclosed system may cause lightning strike locations to be presented in varying colors and shapes to indicate the strength of individual strikes, the density of occurrences in certain areas, the frequency of strike in the area, etc. The system may include a user interface that allows the user to input data such as location and to select the range scale for viewing bearing and distance to the occurrence of interest. In some embodiments, the output may also be shared with similar devices to improve the accuracy of each device.

The techniques, apparatuses, and systems described herein may be implemented in a number of ways. Example implementations are provided below with reference to the following figures.

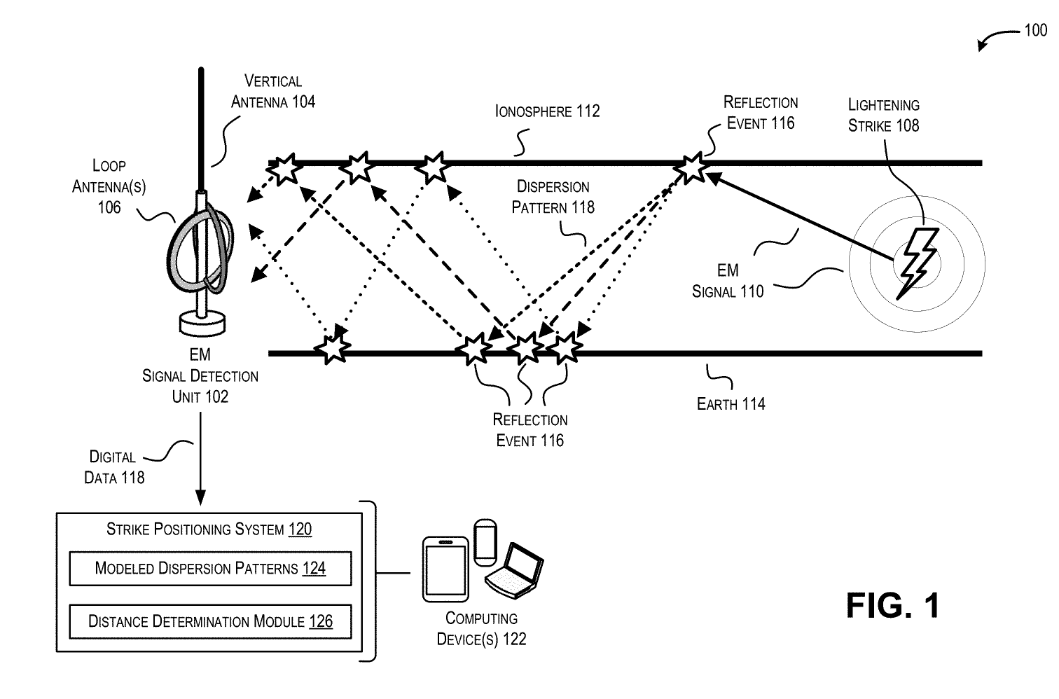

FIG. 1 is a schematic diagram of an illustrative environment 100 for determining the location of lightning strikes. The environment 100 includes an EM signal detection unit 102 that comprises at least a vertical antenna 104 and two perpendicular loop antennae 106. The vertical antenna 104 may be configured to detect electric fields, and loop antennas 106 may be configured to detect magnetic fields.

FIG. 1 further illustrates a lightning strike 108 and an EM signal 110 that is propagating away from the location of the lightning strike 108. FIG. 1 shows ionosphere 112 and the earth 114 acting as a waveguide that guides the EM signal 110 as it propagates towards the EM signal detection unit 102. FIG. 1 illustrates multiple reflection events 116 where EM signal 110 strikes and is reflected by the ionosphere 112 and earth 114. Because different frequencies are reflected at different angles, the first time the EM signal 110 is reflected by a reflection event 116, this first reflection event 116 causes the EM signal 110 to exhibit a dispersion pattern 118. Then, for each subsequent reflection event 116 where the EM signal 110 is reflected by one of the ionosphere 112 and the earth 114, the dispersion pattern 116 exhibited by the EM signal is modified 110.

When the EM signal 110 reaches the EM signal detection unit 102, the EM signal 110 is detected by the vertical antenna 104 and the loop antennas 106. The EM signal detection unit 102 may then convert the received EM signal 110 into digital data 118, and transmit the digital data 118 to a strike positioning system 120.

In some embodiments, the strike positioning system 120 is executed on a computing device 122 associated with the EM signal detection unit 102. The computing device 118 may correspond to any type of computing entity, such as a smartphone, smart camera, tablet, personal computer, laptop, voice controlled computing device, server system, or other computing system that is able to execute and/or present one or more functionalities associated with the strike positioning system 120. In some embodiments, the computing device 122 is incorporated into the EM signal detection unit 102.

FIG. 1 illustrates that strike positioning system 120 as including modeled dispersion patters 124 and a distance determination module 126. The modeled dispersion patterns 124 may include one or more dispersion models that individually correspond to a particular distance.

In some embodiments, the modeled dispersion patterns 124 are generated by the strike positing system 120. Because different EM frequencies are reflected by the ionosphere 112 and earth 114, and because the frequencies present in an EM signal 110 are known, the strike positioning system 120 may determine a modeled dispersion pattern 124 for a given distance. That is, the strike positioning system 120 may calculate the dispersion pattern 118 that an EM signal 110 would be expected to exhibit at a given distance.

The distance determination module 126 may be configured to perform one or more processing steps to filter, amplify, and/or otherwise prepare the digital data 118. For example, the distance determination module 126 may determine the power of each part of the spectrum of frequencies contained in the EM signal 110, strength of different frequencies, verify the source of the EM signal 110 as corresponding to a lightning strike, isolate one or more portions of the frequency spectrum that corresponds to lightning strikes (e.g., higher portions of the spectrum for cloud to cloud strikes, lower portions of the spectrum for cloud to ground strikes), correct for offsets, determine the phase of the signal, etc.

The distance determination module 126 may then use the prepared digital data 118 and the modeled dispersion patterns 124 to determine a distance between the EM signal detection unit 102 and the location of the lightning strike 108. The distance determination module 126 may determine the distance that an EM signal 110 has traveled based on the dispersion pattern 118 that it exhibits. For example, the distance determination module 126 may employ enhanced digital signal processing, probabilistic methods, most likely estimate (MLE) algorithms, near signal phase relationships, or a combination thereof to match the dispersion pattern of the EM signal 110 to a modeled dispersion pattern 124 for a corresponding distance. In this way, by determining the modeled dispersion pattern 124 that the EM signal 110 most closely resembles, the distance determination module 126 is able to determine the distance between the EM signal detection unit 102 and the location of the lightning strike 108.

The strike positioning system 120 may then generate and present a visual display, an audible output, or a combination thereof. For example, the strike positioning system 120 may cause the computing device 122 to present a user interface that displays lightning strike locations in varying colors and shapes to indicate the strength of individual strikes, the density of occurrences in certain areas, the frequency of strike in the area, etc. In some embodiments, the user interface may be configured to receive inputs such as a location, a selection of a range scale for viewing, etc.

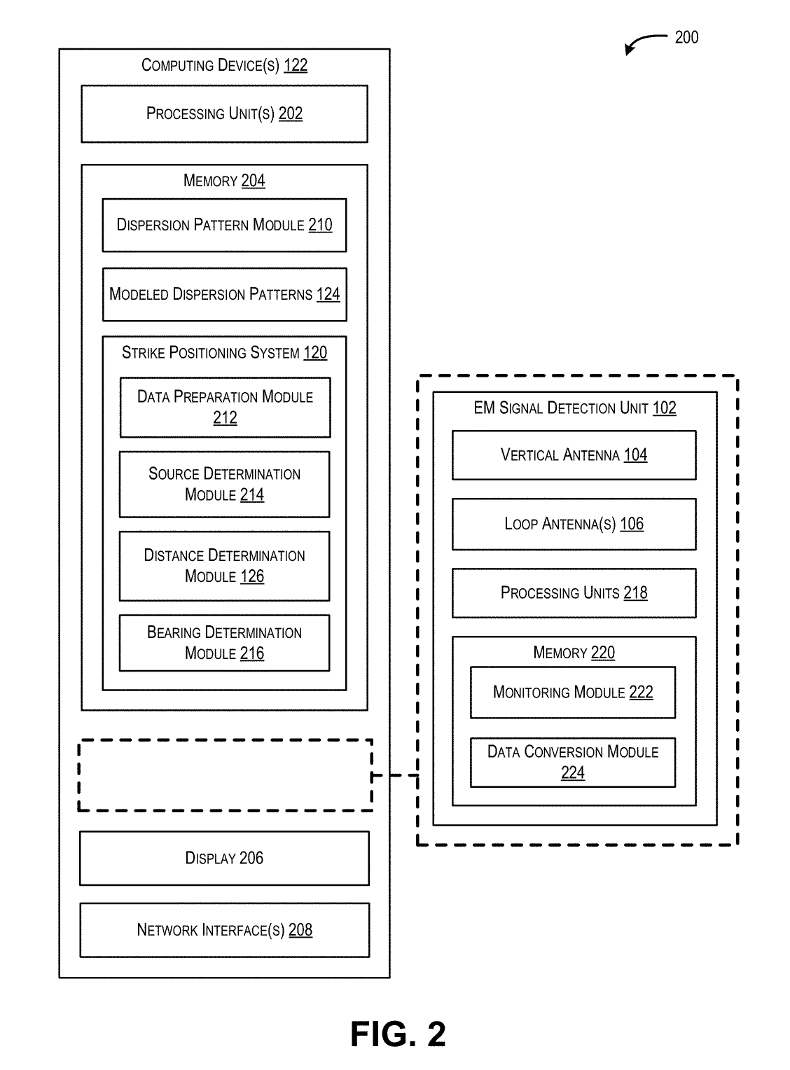

FIG. 2 is a block diagram of an illustrative computing architecture 200 for determining the positions of lightning strikes. The computing architecture 200 may be used to implement the various systems, devices, and techniques discussed above. In the illustrated implementation, the computing device 122 includes one or more processing units 202 coupled to a memory 204. The computing architecture 200 may also include a display 206 and a network interface 208. The network interface 208 may include physical and/or logical interfaces for connecting the respective computing device 122, to one or more EM signal detection unit(s) 102, networks, other computing devices, etc. For example, the network interface 208 may enable WiFi-based communication such as via frequencies defined by the IEEE 802.11 standards, short range wireless frequencies such as Bluetooth®, or any suitable wired or wireless communications protocol that enables the respective computing device to interface with other computing devices.

The computing device 122 can include a dispersion pattern module 210 and modeled dispersion patterns 124 stored on the memory 204. As used herein, the term “module” is intended to represent example divisions of executable instructions for purposes of discussion, and is not intended to represent any type of requirement or required method, manner or organization. Accordingly, while various “modules” are described, their functionality and/or similar functionality could be arranged differently (e.g., combined into a fewer number of modules, broken into a larger number of modules, etc.). Further, while certain functions and modules are described herein as being implemented by software and/or firmware executable on a processor, in other instances, any or all of the modules can be implemented in whole or in part by hardware (e.g., a specialized processing unit, etc.) to execute the described functions. In various implementations, the modules described herein in association with user computing device 102 can be executed across multiple devices.

The dispersion pattern module 210 can be executable by the one or more processing units 202 to determine modelled dispersion patterns 124. As discussed above in the remarks regarding FIG. 1, the ionosphere and the earth act as a waveguide that guides EM signals as they propagate. Additionally, when EM signals are reflected by the ionosphere and/or earth the subsequent reflection imparts dispersive effects on the EM signals such that they exhibit a dispersion pattern. That is, the characteristics of the ionosphere, and the differing wavelengths present in the EM signal cause these differing frequencies to propagate through the waveguide at differing speeds.

Because the dispersion effects imparted by the ionosphere and/or earth can be predicted (i.e., dispersion effects of a reflection cause predictable outcomes based on the frequency of the EM signal that is being reflected), and because the frequencies present in an EM signal are known (i.e., the spectral density of an EM signal is known), the dispersion pattern module 210 may calculate the dispersion patterns that can be expected to be present in an EM signal as it propagates. That is, because the dispersion induced by reflections off the ionosphere and the earth are calculable, the dispersion pattern module 210 may determine the individual modeled dispersion patterns 124 correspond to the dispersion pattern that an EM signal would be expected to have after traveling particular distances.

In some embodiments, determining the individual modeled dispersion patterns may include one or more of determining, an expected amplitude of the spectrum of the EM signal, an expected phase delay across a particular frequency range, an expected signal shape for the EM signal, etc. For example, the amplitude of the spectrum that is expected for an EM signal may be derived from the formula:

$$A ( ω ) = cos ( \frac{π ( ω - ω a )}{2 ω r} ) \qquad ( 1 )$$

where ω is radian frequency, ωa is the spectral peak frequency ωr is the half power point frequency and ω represents the frequency range under consideration. Additionally, the dispersion pattern module 210 may determine an expected phase delay over a chosen frequency range using the formula:

ϕ(ω)=ω/c\sqrt{1−ω0²/ω²} (2)

Where ω0 is the lowest radian frequency sustainable and/or sustained by the earth/ionosphere wave guide, ω is the frequency of interest and c is the velocity of light. Moreover, the dispersion pattern module 210 may estimate an expected signal shape for an EM signal after it has propagated though the waveguide (i.e., between the ionosphere and the earth) a function of distance from the source of the lightning event using the formula:

$$signal ( r , t , ω ) = A ( ω ) cos ( ( t + \frac{r}{c} ) * ω - r * φ 0 ) / φ ( ω ) \qquad ( 3 )$$

Alternatively, or in addition, the dispersion pattern model may determine the modeled dispersion patterns 124 based on historical data that depicts previously detected dispersion patterns associated with prior lightning strikes. For example, the dispersion pattern module 210 may group previously detected dispersion patterns that correspond to EM signals that have traveled the same distance. In some embodiments, the dispersion pattern module 210 may further determine commonalities between the dispersion patterns within individual groups.

The modeled dispersion patterns 124 may correspond to data that indicates dispersion patterns that an EM signal is expected to exhibit at different distances of travel. In other words, the modeled dispersion patterns 124 may comprise individual modeled dispersion patterns that individual indicate what an EM signal would be expected to look like at a particular distance of travel from the location of the lightning strike. The modeled dispersion patterns 124 may be determined by the dispersion pattern module 124, may be received from another computing device, received via inputs into the computing device (i.e., user inputs, sensor inputs, etc.), or a combination thereof.

FIG. 2 depicts a strike positioning system 120 configured to determine the location of lightning strikes being stored in the memory 204. FIG. 2 illustrates strike positioning system 120 as including a data preparation module 212, source determination module 214, distance determination module 126, and bearing determination module 216.

The data preparation module 212 can be executable by the one or more processing units 202 to process, filter, and/or otherwise prepare digital data corresponding to detected EM signals for analysis by the strike positioning system 120. In some embodiments, the data preparation module 212 may selectively determine the power in each part of the spectrum of frequencies contained in digital data corresponding to an EM signal, and/or normalize the digital data such that the power of the frequencies contained in the digital data is comparable across EM signals. For example, the data preparation module 212 may adjust the power of frequencies in the digital data to a set value/range, such that each normalized instance of digital data that corresponds to an EM signal has equivalent power. This may be done prior to further processing to neutralize the effect of signal level (i.e., power) in determining how the EM signals relate to each other from a frequency and/or phase relation standpoint.

The data preparation module 212 may also filter the EM signal by increasing one or more frequency ranges to focus on one or more areas of the electromagnetic spectrum, reduce one or more frequency ranges to minimize one or more areas of the electromagnetic spectrum, or a combination thereof. In some embodiments, the data preparation module 212 may also use Fourier Analysis to find the relative strengths of certain frequencies within the EM signal and/or determine the phase relation between certain frequencies of the EM signal. The data preparation module 212 may also identify one or more maximum values for the EM signal as detected by the vertical antenna, the one or more loop antennas, or a combination thereof.

The source determination module 214 can be executable by the one or more processing units 202 to determine whether a source for the EM signal in a lightning event (i.e., a cloud to cloud lightning strike, a cloud to ground lightning strike, etc.). In some embodiments, the source determination module 214 may compare the duration of a received EM signal to one or more known durations that correspond to a lightning event to determine whether the source of the EM signal is a lightning event. In some embodiments, based on the relative phases of the electronic field and magnetic field portions of the EM signal, the source determination module 214 may determine that a EM signal originated from a cloud to cloud lightning event (i.e., lighting traveling within a cloud or from a first cloud to a second cloud), and not a cloud to earth lightning event (i.e., lightning traveling from a cloud to the earth).

In some embodiments, the source determination module 214 may do this by time shifting at least a portion of the EM signal received via the vertical antenna (i.e., the electronic field portion of the EM signal), the one or more portions received via the one or more loop antennas (i.e., magnetic field portions of the EM signal), with respect to each other to find a maximum correlation between the electric and magnetic portions of the EM signal. The source determination module 124 may then use the number of samples shifted, the sample time and the frequencies of the EM signal to determine the relative phases of the EM signal. Alternatively or in addition, the source determination module 214 may use such time shifting to determine the phase differences of the electric and magnetic portions of the EM signal. The source determination module 214 may then use the phase differences between the electric field and magnetic field portions of the EM signal to estimate a likelihood that the EM signal corresponds to a lightning event.

The source determination module 214 may also compare the amplitudes of the electric field and magnetic field portions of the EM signal to eliminate local noise and to determine whether there is sufficient signal strength to validate the source and to perform reliable signal analysis. For example, if the source determination module 214 determines that one or more of the electric field and magnetic field portions of the EM signal does not have a threshold amplitude, the source determination module 214 may determine that the received EM signal corresponds to local noise, and not to a lightning event. In some embodiments, the source determination module 214 may compare the relative amplitudes of the electric field and magnetic field portions of the EM signal to known ratios for the amplitudes of EM signals that correspond to lightning events. Alternatively, or in addition, the source determination module 214 may determine the source the EM signal based at least in part on the relative amplitudes of different areas of the EM spectrum of the EM signal.

In some embodiments, the source determination module 214 may determine the source the EM signal based at least in part on the symmetry of the received EM signal. Because lightning events are known to demonstrate a certain symmetry in the electromagnetic fields they generate, the source determination module may determine that EM signals that do not match this profile do not correspond to lightning events.

In some embodiments, the source determination module 214 may determine the source the EM signal based on a combination of the processes described above. Additionally, in some embodiments the source determination module 214 may use a weighting method that adjusts the weight of lower priority processes according to the levels of higher priority process.

The distance determination module 126 can be executable by the one or more processing units 202 to determine the distance associated with the EM signal. The determining of the distance may include determining a distance between the EM signal detection unit 102 and the location of the EM event. In some embodiments, the distance determination module 126 may utilize the modeled dispersion patterns 124 to determine the distance between the lightning event and the EM signal detection unit 102. For example, the distance determination module 126 may correlate a detected EM signal with one or more of the modeled dispersion patterns 124 to establish a Most Likely Estimate (MLE).

In some embodiments, the distance determination module 126 may determine the modeled dispersion pattern that best matches the received EM signal by iteratively comparing the pattern of the received EM signal to one or more of the modeled dispersion patterns. When performing this comparison, the distance determination module 126 may cause the frequency ranges of the EM signal to be shifted in time with relation to an individual modeled dispersion pattern until the distance determination module 126 identifies a position that represents the best match between the received EM signal and the individual modeled dispersion pattern. The distance determination module 126 may then determine which of the individual modeled dispersion patterns represents the best match, a corresponding degree of correlation, and/or the sample shift required to identify the best match.

That is, the distance determination module 126 may identify an individual modeled dispersion pattern that the detected EM signal most strongly correlates (i.e., that is the best match, has a match above a predetermined threshold, a combination thereof, etc.), and determine that the distance to which the individual modeled dispersion pattern corresponds is the most likely distance between the lightning event and the EM signal detection unit 102.

Alternatively, or in addition, the distance determination module 126 may determine the distance between the lightning event and the EM signal detection unit 102 based at least in part on the phase and/or amplitude relation of detected EM signals. For example, when the distance between the lightning event and the EM signal detection unit 102 correspond to a small number of wavelengths, particular spectrums of the electric and magnetic fields of EM signals exhibit phase and amplitude relationships. Therefore, by modeling relationships between phase relationships for EM signals at specific frequencies, and comparing the modeled relationships to the detected EM signals, the distance determination module 126 may determine the distance between the lightning event and the EM signal detection unit 102.

Alternatively, or in addition, because the dispersion pattern created by an earth/ionosphere waveguide can be formulaically determined as a function of distance, the distance determination module 126 may in some embodiments determine a distance to the source of the EM signal using one or more formulas. For example, the distance determination module 126 may determine the distance value that, when plugged into one or more formulas for modeling the effects of the earth/ionosphere waveguide on EM signals, results in a dispersion pattern that best matches the received EM signal.

In some embodiments, the distance determination module 126 may determine a confidence level associated with the determined distance between the lightning event and the EM signal detection unit 102.

The distance determination module 126 may determine the distance between the lightning event and the EM signal detection unit 102 based on the distance from magnitude of the EM signal. For example, the distance determination module 126 may determine the distance from magnitude using the formula:

DM=K/\sqrt{x²+ŷ2}. (4)

The value of K is a function of the Power Spectral Density (PSD) of EM signals and any difference between the distance determined using magnitude and the distance determined using the modeled dispersion patterns 124. That is, K may be a calibration factor that accounts for environmental conditions/interference (e.g., the atmosphere, conductivity of the earth, surrounding structures, moisture, etc.) on the magnitude of EM signals. A PSD is an indicator of the strength of a lightning event (e.g., higher PSD at the lower frequencies correlates well with stronger EM occurrences). The value of K may be determined based on a comparison between first distances determined based on the magnitude of one or more EM signals and second distances determined based on the dispersion pattern of the same one or more EM signals. Once the distance determination module 126 identifies the effects of the environmental conditions, it may determine an environmental adjustment to the value of K to calibrate for the local environmental conditions of the EM signal detection unit 102.

In some embodiments, for shorter distances, the distance determination module 126 may determine the distance between the lightning event and the EM signal detection unit 102 by treating the EM signal detection unit 102 as a Hertzian dipole, and using the formulas:

Hϕ=Io*d1/4Π*sin θ*[jβ/r+1/r²]e^{-jβr} (5)

Eθ=Io*d1/4Π*sin θ*[jβ/r+1/r²−j/βr³]e^{-jβr} (6)

Where Hϕ is the Magnetic Field Strength in the ϕ direction, Eθ is the Electric Field Strength in the θ direction, Io is the current flowing in the dipole or lightning channel, d1 is the length of the antenna or lightning channel, θ is the angle observed above or below the center of the channel, j is the square root of −1, and β=2*Π/λ, where λ is the wavelength of the signal of interest and λ is equal to velocity/frequency. Since we are dealing with EM waves, velocity in this case is c the speed of light. The strength and phase of the magnetic field and the electric field vary based on both (1) the distance from the source of the EM signal, and (2) with the frequencies present in the EM signal. Therefore, the phase between the magnetic field and the electric field may be used to determine the distance between the source of the EM signal and the EM signal detection unit, when the source of the EM signal is located within a few wavelengths of the EM signal. In this way, because β is frequency dependent, the distance determination module may determine the distance for close distances as a function of frequency by comparing the phase of the magnetic field to the electric field, or the electric field to magnetic field.

The bearing determination module 216 can be executable by the one or more processing units 202 to determine a bearing between the EM signal detection unit and the location of the EM signal. For example, the bearing determination module 216 may determine the bearing of the EM signal based on the relative magnitudes of the incoming signal received on the orthogonal magnetic sensors (i.e., the loop antenna). In some embodiments, the bearing determination module 216 may validate the bearing of the EM signal the disclosed methods and systems determine bearing to the source by using the polarization of the EM signal. Because the earth's magnetic field penetrates the ionosphere, EM signals are reflected by two different refractive indices. Accordingly, linearly polarized waves traveling through the ionosphere are reflected as elliptically polarized waves because the orthogonal magnetic fields characteristic of these waves are effected differently due to their different orientation to the earth's magnetic field within the ionospheric plasma. The resulting waves are conventionally known as ordinary and extra-ordinary waves. The resulting polarization is dependent on the angular relationship between the EM source, the earth's magnetic field and the sensor. This polarization or phase can be determined by the bearing determination module 216 from the differential arrival times of the EM signal received at the two orthogonal magnetic antennas. The time delay and the phase between EM signals may be determined based on a series of correlations. Accordingly, the bearing determination module 216 may use this polarization information and the known location of the EM signal detection unit 102, to validate the bearing of the EM signal to the lightning event. Alternatively, or in addition, the bearing determination module 216 may also compare the phase of the electric field portion of the EM signal to the phase of the one or more magnetic field portions of the EM signal to verify a bearing of the EM signal.

FIG. 2 further depicts EM signal detection unit 102 having a vertical antenna 104 and one or more loop antennas 106. EM signal detection unit 102 may be a component of computing device 122, or may be an independent device. In some embodiments, EM signal detection unit 102 may further include processing unit(s) 218, and memory 220. The EM signal detection unit 102 can include a monitoring module 222 and a data conversion module 224. The monitoring module 222 can be executable by the one or more processing units 218 to monitor field levels detected by one or more of the vertical antenna 104 and the loop antennas 106 to identify field levels indicative of an EM signal. The data conversion module 224can be executable by the one or more processing units 218 to convert the field levels detected by one or more of the vertical antenna 104 and the loop antennas 106 to digital data.

Those skilled in the art will appreciate that the computing architecture 200 is merely illustrative and is not intended to limit the scope of the present disclosure. In particular, the computing system and devices may include any combination of hardware or software that can perform the indicated functions, including computers, network devices, internet appliances, PDAs, wireless phones, pagers, etc. The computing architecture 200 may also be connected to other devices that are not illustrated, or instead may operate as a stand-alone system. In addition, the functionality provided by the illustrated components may in some implementations be combined in fewer components or distributed in additional components. Similarly, in some implementations, the functionality of some of the illustrated components may not be provided and/or other additional functionality may be available.

The one or more processing unit(s) 202 and 218 may be configured to execute instructions, applications, or programs stored in the memories 204 and 220. In some examples, the one or more processing unit(s) 202 and 218 may include hardware processors that include, without limitation, a hardware central processing unit (CPU), a graphics processing unit (GPU), and so on. While in many instances the techniques are described herein as being performed by the one or more processing units 202 and 218, in some instances the techniques may be implemented by one or more hardware logic components, such as a field programmable gate array (FPGA), a complex programmable logic device (CPLD), an application specific integrated circuit (ASIC), a system-on-chip (SoC), or a combination thereof.

The memories 204 and 220 are examples of computer-readable media. Computer-readable media may include two types of computer-readable media, namely computer storage media and communication media. Computer storage media may include volatile and non-volatile, removable, and non-removable media implemented in any method or technology for storage of information, such as computer readable instructions, data structures, program modules, or other data. Computer storage media includes, but is not limited to, random access memory (RAM), read-only memory (ROM), erasable programmable read-only memory (EEPROM), flash memory or other memory technology, compact disc read-only memory (CD-ROM), digital versatile disk (DVD), or other optical storage, magnetic cassettes, magnetic tape, magnetic disk storage or other magnetic storage devices, or any other non-transmission medium that may be used to store the desired information and which may be accessed by a computing device. In general, computer storage media may include computer-executable instructions that, when executed by one or more processing units, cause various functions and/or operations described herein to be performed. In contrast, communication media embodies computer-readable instructions, data structures, program modules, or other data in a modulated data signal, such as a carrier wave, or other transmission mechanism. As defined herein, computer storage media does not include communication media.

Those skilled in the art will also appreciate that, while various items are illustrated as being stored in memory or storage while being used, these items or portions of them may be transferred between memory and other storage devices for purposes of memory management and data integrity. Alternatively, in other implementations, some or all of the software components may execute in memory on another device and communicate with the illustrated computing architecture 200. Some or all of the system components or data structures may also be stored (e.g., as instructions or structured data) on a non-transitory, computer-accessible medium or a portable article to be read by an appropriate drive, various examples of which are described above. In some implementations, instructions stored on a computer-accessible medium separate from the computing architecture 200 may be transmitted to the computing architecture 200 via transmission media or signals such as electrical, electromagnetic, or digital signals, conveyed via a communication medium such as a wireless link. Various implementations may further include receiving, sending or storing instructions and/or data implemented in accordance with the foregoing description upon a computer-accessible medium.

The architectures, systems, and individual elements described herein may include many other logical, programmatic, and physical components, of which those shown in the accompanying figures are merely examples that are related to the discussion herein.

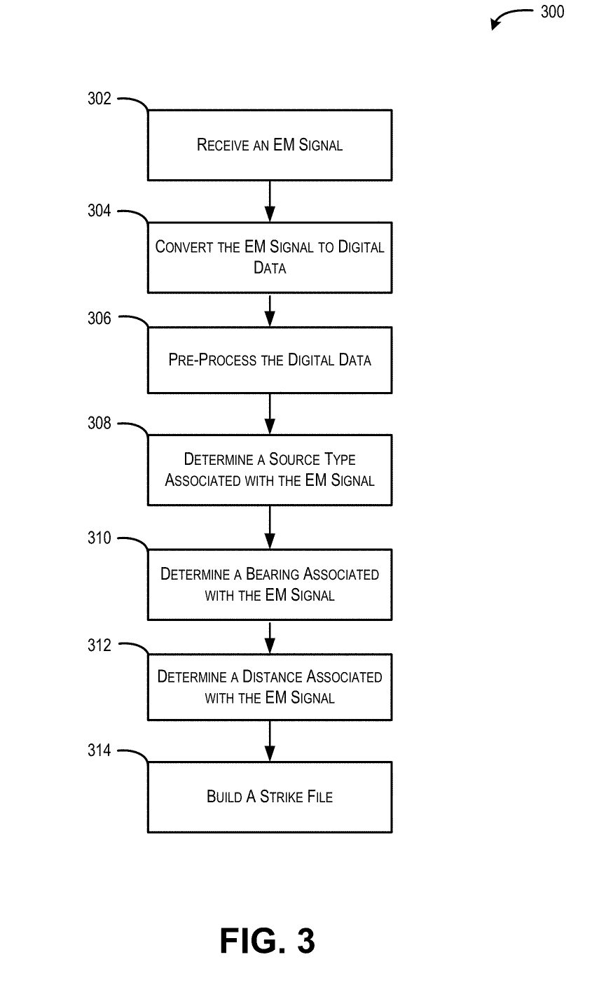

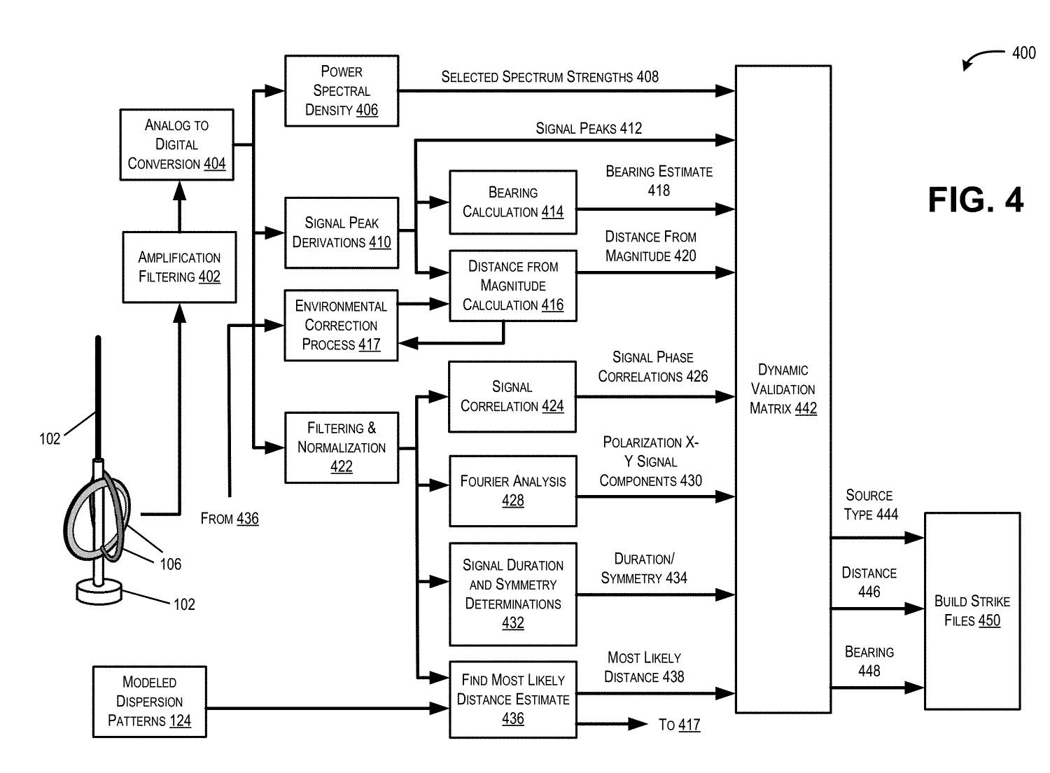

FIGS. 3 and 4 are flow diagrams of illustrative processes illustrated as a collection of blocks in a logical flow graph, which represent a sequence of operations that can be implemented in hardware, software, or a combination thereof. In the context of software, the blocks represent computer-executable instructions stored on one or more computer-readable storage media that, when executed by one or more processors, perform the recited operations. Generally, computer-executable instructions include routines, programs, objects, components, data structures, and the like that perform particular functions or implement particular abstract data types. The order in which the operations are described is not intended to be construed as a limitation, and any number of the described blocks can be combined in any order and/or in parallel to implement the processes.

FIG. 3 is a flow diagram of an illustrative process 300 to determine the location of lightning events. The process 300 may be implemented in the environment 100 and by the computing architecture 200 described above, or in other environments and architectures.

At 302, the EM signal detection unit 102 receives an EM signal. The EM signal detection unit 102 may include a vertical antenna that detect local electric field information, and one or more loop antennas (e.g., perpendicular loop antenna) that detect local magnetic field information. Receiving the EM signal may correspond to the vertical antenna and the one or more loop antennas detecting a change in the local electric and magnetic fields that is indicative of an EM signal.

At 304, the received EM signal is converted to digital data. For example, the changes in the local electric and magnetic fields detected by one or more of the vertical antenna and the loop antennas may be converted to digital data that can be interpreted or otherwise processed by a computing device.

At 306, the strike positioning system 120 pre-processes the digital data. Pre-processing the digital data may include processing, filtering and/or otherwise preparing the digital data corresponding to the EM signals for analysis by the strike positioning system 120. In some embodiments, the strike positioning system 120 may selectively determine the power in each part of the spectrum of frequencies contained in digital data corresponding to an EM signal, and/or normalize the digital data such that the power of the frequencies contained in the digital data is comparable across EM signals. For example, the strike positioning system 120 may adjust the power of frequencies in the digital data to a set value/range, such that each normalized instance of digital data that corresponds to an EM signal has equivalent power

In some embodiments, one or more frequency ranges of the EM signal may be shifted in time ahead or behind one or more other frequency ranges of the EM signal, until the strike positioning system 120 determines a best match, a degree of correlation, and the sample shift required for the best match. The strike positioning system 120 may then use the number of samples shifted, the sample time and the frequencies of the EM signal to determine the relative phase of the two portions of the EM signal.

The strike positioning system 120 may also filter the EM signal by increasing one or more frequency ranges to focus on one or more areas of the electromagnetic spectrum, reduce one or more frequency ranges to minimize one or more areas of the electromagnetic spectrum, or a combination thereof In some embodiments, the strike positioning system 120 may also use Fourier analysis is to find the relative strengths of certain frequencies within the EM signal and/or determine the phase relation between certain frequencies and the EM signal. The strike positioning system 120 may also identify one or more maximum values for the EM signal as detected by the vertical antenna, the one or more loop antennas, or a combination thereof.

At 308, the strike positioning system 120 determines a source type associated with the EM signal. Determining a source type associated with the EM signal may correspond to determining whether a source for the EM signal is a lightning event (i.e., a cloud to cloud lightning strike, a cloud to ground lightning strike, etc.). In some embodiments, the strike positioning system 120 may compare the duration of a received EM signal to one or more known durations that correspond to a lightning event to determine whether the source of the EM signal is a lightning event. The strike positioning system 120 may also compare the phase of the electric field portion of the EM signal to the phase of the Magnetic Field portion of the EM signal to determine the source of the EM signal.

In some embodiments, the strike positioning system 120 may do this by time shifting at least a portion of the EM signal received via the vertical antenna (i.e., the electronic field portion of the EM signal), the one or more portions received via the one or more loop antennas (i.e., magnetic field portions of the EM signal), with respect to each other to find a maximum correlation between the electric and magnetic portions of the EM signal. Alternatively, or in addition, the strike positioning system 120 may use such time shifting to determine the phase differences of the electric and magnetic portions of the EM signal. The strike positioning system 120 may then use the phase differences between the electric field and magnetic field portions of the EM signal to estimate a likelihood that the EM signal corresponds to a lightning event.

The strike positioning system 120 may also compare the amplitudes of the electric field and magnetic field portions of the EM signal to eliminate local noise and to determine whether there is sufficient signal strength to validate the source and to perform reliable signal analysis. For example, if the strike positioning system 120 determines that one or more of the electric field and magnetic field portions of the EM signal does not have a threshold amplitude, the strike positioning system 120 may determine that the received EM signal corresponds to local noise, and not to a lightning event. In some embodiments, the strike positioning system 120 may compare the relative amplitudes of the electric field and magnetic field portions of the EM signal to known ratios for the amplitudes of EM signals that correspond to lightning events. Alternatively, or in addition, the strike positioning system 120 may determine the source the EM signal based at least in part on the relative amplitudes of different areas of the EM spectrum of the EM signal.

In some embodiments, the strike positioning system 120 may determine the source the EM signal based at least in part on the symmetry of the received EM signal. Because lightning events are known to demonstrate a certain symmetry in the electromagnetic fields they generate, the strike positioning system 120 may determine that EM signals that do not match this profile do not correspond to lightning events.

In some embodiments, the strike positioning system 120 may determine the source the EM signal based on a combination of the processes described above. Additionally, in some embodiments the strike positioning system 120 may use a weighting method that adjusts the weight of lower priority processes according to the levels of higher priority process.

At 310, the strike positioning system 120 determines a bearing associated with the EM signal. Determining the bearing associated with the EM signal may include determining a bearing between the EM signal detection unit and the location of the EM signal. For example, the strike positioning system 120 may determine the bearing of the EM signal based on the relative magnitudes of the incoming signal received on the orthogonal magnetic sensors (i.e., the loop antenna). In some embodiments, the strike positioning system 120 may validate the bearing of the EM signal to the source by using the polarization of the EM signal. Because the earth's magnetic field penetrates the ionosphere, EM signals are reflected by two different refractive indices. Accordingly, linearly polarized waves traveling through the ionosphere are reflected as elliptically polarized waves because the orthogonal magnetic fields characteristic of these waves are effected differently due to their different orientation to the earth's magnetic field within the ionospheric plasma. The resulting waves are conventionally known as ordinary and extra-ordinary waves. The resulting polarization is dependent on the angular relationship between the EM source, the earth's magnetic field and the sensor. This polarization or phase can be determined by the strike positioning system 120 from the differential arrival times of the EM signal received at the two orthogonal magnetic antennas. The time delay and the phase between EM signals may be determined based on a series of correlations. Accordingly, the strike positioning system 120 may use this polarization information and the known location of the EM signal detection unit 102, to validate the bearing of the EM signal to the lightning event.

At 312, the strike positioning system 120 determines a distance associated with the EM signal. Determining the distance associated with the EM signal may include determining a distance between the EM signal detection unit 102 and the location of the EM event. In some embodiments, the strike positioning system 120 may utilize the modeled dispersion patterns 124 to determine the distance between the lightning event and the EM signal detection unit 102. For example, the strike positioning system 120 may correlate a detected EM signal with one or more of the modeled dispersion patterns 124 to establish a Most Likely Estimate (MLE). That is, the strike positioning system 120 may identify an individual modeled dispersion pattern that the detected EM signal most strongly correlates (i.e., that is the best match, has a match above a predetermined threshold, a combination thereof, etc.), and determine that the distance to which the individual modeled dispersion pattern corresponds is the most likely distance between the lightning event and the EM signal detection unit 102.

Alternatively, or in addition, the strike positioning system 120 may determine the distance between the lightning event and the EM signal detection unit 102 based at least in part on the phase and/or amplitude relation of detected EM signals. For example, when the distance between the lightning event and the EM signal detection unit 102 correspond to a small number of wavelengths, particular spectrums of the electric and magnetic fields of EM signals exhibit phase and amplitude relationships. Therefore, by modeling relationships between phase and amplitude relationships for EM signals at specific frequencies, and comparing the modeled relationships to the detected EM signals, the strike positioning system 120 may determine the distance between the lightning event and the EM signal detection unit 102. In some embodiments, the strike positioning system 120 may determine a confidence level associated with the determined the distance between the lightning event and the EM signal detection unit 102.

The strike positioning system 120 may determine the distance between the lightning event and the EM signal detection unit 102 based on the distance from magnitude of the EM signal. For example, the strike positioning system 120 may determine the distance from magnitude using the formula:

DM=K/\sqrt{x²+ŷ2}. (4)

The value of K is a function of the Power Spectral Density (PSD) of EM signals and any difference between the distance the strike positioning system 120 determined using magnitude and the distance the strike positioning system 120 determined using the modeled dispersion patterns 124. For example, the PSD may be used to adjust the K factor and to adjust for distances of cloud to cloud vs cloud to ground strikes. A PSD is an indicator of the strength of a lightning event (e.g., higher PSD at the lower frequencies correlates well with stronger EM occurrences).

At 314, the strike positioning system 120 builds a strike file. A strike file may correspond to computer data to facilitate presentation of lighting strike information on a user interface, sharing of lighting strike information with other devices, etc. For example, a strike file may identify a source type for the EM signal, a bearing and/or distance from the EM source to the EM signal detection unit, a date and time the EM signal was received, EM signal magnitudes, or other information about the received EM signal. In some embodiments, the strike file may be utilized to presented EM strike information to a user. For example, the information included in a strike file may be used to generate a graphical user interface that visually indicates the information for consumption by a user. The graphical user interface may be presented on a display associated with the EM signal detection unit, the computing device, or another computing device. In some embodiments, strike files may be shared between multiple strike positioning systems 120, a central server, or a combination thereof to enable the verification of EM signals, calibration of individual EM signal detection units, further research and development relating to EM source detection, etc.

FIG. 4 is a flow diagram of an illustrative process 400 for transforming EM signals detected by the EM signal detection unit into strike files. The process 400 may be implemented in the environment 100 and by the computing architecture 200 described above, or in other environments and architectures.

FIG. 4 depicts EM signal detection unit 102 having a vertical antenna 104 and one or more loop antennas 106. The vertical antenna 104 may be configured to detect electric fields, and loop antennas 106 may be configured to detect magnetic fields. The EM signal detection unit 102 may be configured to monitor electric and magnetic field levels detected by one or more of the vertical antenna 104 and the loop antennas 106, and to identify changes in field levels that are indicative of an EM signal from a lightning event.

When an EM signal is detected by the EM signal detection unit 102, the EM signal detection unit 102 may perform one or more amplification filtering processes 402 on the detected EM signal. For example, the EM signal detection unit 102 may compare the amplitudes of the electric field and magnetic field portions of the EM signal to eliminate local noise. The EM signal detection unit 102 may also use such a comparison to determine whether there is sufficient signal strength to validate the EM signal was generated by a lightning strike. Alternatively, or in addition, the EM signal detection unit 102 may determine whether one or more of the electric field and magnetic field portions of the EM signal have a threshold amplitude. In this way, the EM signal detection unit 102 is able to separate electric and magnetic field variations that are the result of an EM signal generated by a lighting event from the electric and magnetic field variations that are the result of local noise. The EM signal detection unit 102 may then perform one or more analog to digital conversion processes 404 to convert the electric and magnetic field levels detected by one or more of the vertical antenna 104 and the loop antennas 106 into digital data.

The EM signal detection unit 102 may then perform one or more power spectral density processes 406 to identify spectrum strengths 408 of the EM signal. The data EM signal detection unit 102 may identify one or more maximum values for the EM signal as detected by the vertical antenna, the one or more loop antennas, or a combination thereof. For example, the power spectral density processes 406 may include the performance of a Fourier analysis on the digital data to determine the polarization of the X and Y signal components of the EM signal. In some embodiments, the EM signal detection unit 102 may use Fourier analysis is to find the relative strengths of certain frequencies within the EM signal and/or determine the phase relation between certain frequencies and the EM signal.

The EM signal detection unit 102 may also perform one or more signal peak derivation processes 410 to identify the signal peaks 412 of the EM signal. In some embodiments, the EM signal detection unit 102 may perform one or more of bearing calculation processes 414 and distance from magnitude calculation processes 416 using the signal peaks 412.

The bearing calculation processes 414 may include determining a bearing estimate 418 of the EM signal based on the relative magnitudes of the incoming signal received on the orthogonal magnetic sensors (i.e., the loop antenna). In some embodiments, the EM signal detection unit 102 may also validate the bearing of the EM signal to the source by using the polarization of the EM signal.

The magnitude calculation processes 416 may include determining an estimated distance between the lightning event and the EM signal detection unit 102 based on the distance from magnitude of the EM signal. For example, EM signal detection unit 102 may determine the distance from magnitude 420 using the formula:

DM=K/\sqrt{x²+ŷ2}. (4)

The value of K is a function of the Power Spectral Density (P SD) of EM signals. The EM signal detection unit 102 may adjust the K factor and to account for differences between cloud to cloud vs cloud to ground strikes.

In some embodiments, the magnitude calculation process 416 may output the determined distance from magnitude 420 to environmental correction process 417. Environmental correction process 417 may evaluate the determined distance from magnitude 420, one or more previously determined distance from magnitudes (i.e., distance from magnitudes determined in association with previous EM signals), or a combination thereof to determine an adjustment to the value of K. That is, based on the historical performance of the magnitude calculation process 416, the value of K may be adjusted to optimize the formula for the environment/surroundings of the EM signal detection unit 102.

The EM signal detection unit 102 may also perform one or more filtering and normalization processes 422 to filter and/or otherwise prepare the digital data corresponding to detected EM signals for further analysis.

In some embodiments, the EM signal detection unit 102 may normalize the digital data such that the power of the frequencies contained in the digital data is comparable across EM signals. The EM signal detection unit 102 may also filter the EM signal by increasing one or more frequency ranges to focus on one or more areas of the electromagnetic spectrum, reduce one or more frequency ranges to minimize one or more areas of the electromagnetic spectrum, or a combination thereof

The EM signal detection unit 102 may then perform one or more signal correlation processes 424 on the normalized digital data to determine signal phase correlations 426 for the EM signal. For example, the EM signal detection unit 102 may shift one or more frequency ranges of the EM signal in time ahead or behind one or more other frequency ranges of the EM signal, until the EM signal detection unit 102 determines a best match, the degree of correlation, and the sample shift required for the best match. In some embodiments, the EM signal detection unit 102 may then use the number of samples shifted, the sample time and the frequencies of the EM signal to determine the relative phase of the two portions of the EM signal.

The EM signal detection unit 102 may also perform a Fourier Analysis 428 on the normalized digital data to determine the polarization of the X and Y signal components 430 of the EM signal. For example, the EM signal detection unit 102 may also use Fourier analysis is to find the relative strengths of certain frequencies within the EM signal and/or determine the phase relation between certain frequencies and the EM signal. The data EM signal detection unit 102 may also identify one or more maximum values for the EM signal as detected by the vertical antenna, the one or more loop antennas, or a combination thereof.

The EM signal detection unit 102 may then perform one or more signal duration and symmetry determinations processes 432 on the normalized digital data to determine a duration/symmetry 432 for the EM signal. For example, the EM signal detection unit 102 may compare the duration of a received EM signal to one or more known durations that correspond to a lightning event to determine whether the source of the EM signal is a lightning event. The EM signal detection unit 102 may also compare the phase of the electric field portion of the EM signal to the phase of the Magnetic Field portion of the EM signal to determine a symmetry of the components of the EM signal. For example, the EM signal detection unit 102 may determine the source the EM signal based at least in part on the symmetry of the received EM signal.

The EM signal detection unit 102 may then perform one or more processes 436 on the normalized digital data to find the most likely distance estimate 438 for the EM signal. In some embodiments, the EM signal detection unit 102 may utilize the modeled dispersion patterns 124 to determine the distance between the lightning event and the EM signal detection unit 102. Individual modeled dispersion patterns 124 correspond to the dispersion pattern that an EM signal would be expected to have after traveling particular distances.

For example, the EM signal detection unit 102 may correlate a detected EM signal with one or more of the modeled dispersion patterns 124 to establish most likely distance 438. That is, the EM signal detection unit 102 may identify an individual modeled dispersion pattern that the detected EM signal most strongly correlates (i.e., that is the best match, has a match above a predetermined threshold, a combination thereof, etc.), and determine that the distance to which the individual modeled dispersion pattern corresponds is the most likely distance between the lightning event and the EM signal detection unit 102. In some embodiments, the most likely distance estimate 438 may also be provided to the environmental correction process 417, which may use the most likely distance estimate 428 to determine an environmental adjustment factor (e.g., K).

The EM signal detection unit 102 may then utilize a dynamic validation matrix 442 to determine most likely a most likely source type 444, and a distance 446 and bearing 448 of the EM signal. In some embodiments, the dynamic validation matric 442 may determine the source type 444, and a distance 446 and bearing 448 of the EM signal based on one or more of selected spectrum strengths 408, signal peaks 412, bearing estimate 418, distance from magnitude 420, signal phase correlations 426, polarization x-y signal components 430, duration/symmetry 434, and most likely distance 438. In determining the source type 444, and a distance 446 and bearing 448 of the EM signal, the dynamic valuation matrix 442 may use a weighting method that adjusts weights associated with lower priority inputs in relation to weights associated with higher priority inputs.

The EM signal detection unit 102 may then build strike files 450. The strike file may identify a source type for the EM signal, a bearing and/or distance from the EM source to the EM signal detection unit, a date and time the EM signal was received, EM signal magnitudes, or other information about the received EM signal. In some embodiments, the strike file may be utilized to presented EM strike information to a user. For example, the information included in a strike file may be used to generate a graphical user interface that visually indicates the information for consumption by a user. The graphical user interface may be presented on a display associated with the EM signal detection unit, the computing device, or another computing device. In some embodiments, strike files may be shared between multiple EM signal detection unit 102, a central server, or a combination thereof to enable the verification of EM signals, calibration of individual EM signal detection units, further research and development relating to EM source detection, etc.

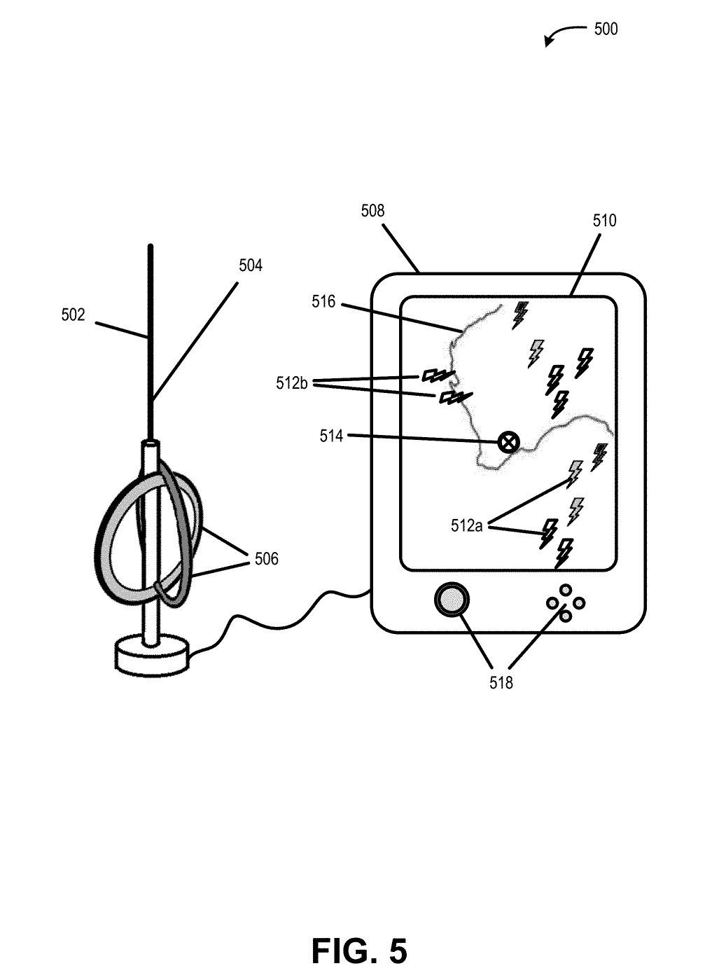

FIG. 5 is a schematic diagram that illustrates an EM signal detection unit and a display showing signal information. FIG. 5 shows an EM signal detection unit 502 that comprises at least a vertical antenna 504 and two perpendicular loop antennae 506. The vertical antenna 504 may be configured to detect electric fields, and loop antennas 506 may be configured to detect magnetic fields.

FIG. 5 further illustrates a computing devices 508 that includes a display 510. The computing device 508 may correspond to any type of computing entity, such as a smartphone, smart camera, tablet, personal computer, laptop, voice controlled computing device, server system, or other computing system. The computing device 508 may cause the display 510 to present a graphical user interface that visually indicates the lightning information 512. In some embodiments the computing device 508 may display a first visual representation of a lighting event 512a in association with cloud to ground strikes, and a second visual representation of a lighting event 512b in association with cloud to cloud or inter-cloud strikes. Lightning information 512 may include the location of lightning strikes, the magnitude of lightning strikes, the time of lightning strikes, etc. The lighting information 512 may also show the density of lightning strikes in a particular area, a path/direction that lightning storms are trending toward, a speed that a lightning storm is moving, a frequency of lightning strikes, an average magnitude for lightning strikes for a lightning storm, etc. The graphical user interface may also include a visual indication 514 of the location of the EM signal detection unit 502. In some embodiments, the graphical user interface may also include a map 516 that shows the geographical surroundings of the EM signal detection unit. The computing device 508 may also include one or more controls 518 that enable a user to control information presented on the display 510, input additional information to the computing device, or both.

### CONCLUSION

Although the subject matter has been described in language specific to structural features and/or methodological acts, it is to be understood that the subject matter defined in the appended claims is not necessarily limited to the specific features or acts described. Rather, the specific features and acts are disclosed as illustrative forms of implementing the claims.

What is claimed is:

1. A system comprising:
an electromagnetic signal detection unit comprising:
a vertical antenna configured to detect local electric fields, and
at least two loop antennae configured to detect local magnetic fields;
one or more processors;
memory; and
one or more computer-executable instructions that are stored in the memory and that are executable by the one or more processors to perform operations comprising:
receiving, by the electromagnetic signal detection unit, an electromagnetic signal associated with a lightning event, the electromagnetic signal exhibiting a detected dispersion pattern;
comparing the detected dispersion pattern to one or more modeled dispersion patterns that each correspond to travel distance characteristics for various electromagnetic signals;
determining that the detected dispersion pattern corresponds to a particular modeled dispersion pattern of the one or more modeled dispersion patterns; and
determining, based on the particular modeled dispersion pattern, an estimated distance between the electromagnetic signal detection unit and the lightning event.

2. The system as recited in claim 1, wherein the operations further comprise:
determining, a first phase of the electric field portion of the electromagnetic signal;
determining, a second phase of a first magnetic field portion of the electromagnetic signal;
determining, a third phase of a second magnetic field portion of the electromagnetic signal; and
determining, based on a relationship between the first phase, the second phase, and the third phase, a bearing between the electromagnetic signal detection unit and the lightning event.

3. The system as recited in claim 2, wherein the first magnetic field portion is detected by a first loop antenna of the at least two loop antenna, the second magnetic field portion is detected by a second loop antenna of the at least two loop antenna, and determining the bearing comprises comparing the second phase to the third phase.

4. The system as recited in claim 1, wherein determining the estimated distance is further based on one or more of:
a phase variance between the electric field portion of the electromagnetic signal and the magnetic field portion of the electromagnetic signal; and
an amplitude variance between the electric field portion of the electromagnetic signal and the magnetic field portion of the electromagnetic signal.

5. A method comprising:
detecting an electromagnetic signal that exhibits a detected dispersion pattern;
comparing the detected dispersion pattern to one or more modeled dispersion patterns that each correspond to travel distance characteristics for various electromagnetic signals;
determining that the detected dispersion pattern corresponds to a particular modeled dispersion pattern of the one or more modeled dispersion patterns; and
determining, based on the particular modeled dispersion pattern, an estimated distance to a source of the electromagnetic signal.

6. The method as recited in claim 5, wherein the electromagnetic signal is detected by an electromagnetic signal detection unit that comprises at least a vertical antenna configured to detect local electric fields, and at least two loop antennae configured to detect local magnetic fields.

7. The method as recited in claim 5, further comprising:
determining a power spectral density associated with the electromagnetic signal;
comparing the power spectral density to one or more modeled power spectral densities, wherein individual modeled power spectral densities correspond to a particular power spectral densities that a modeled electromagnetic signal would be expected to exhibit if it was generated by a particular source;
determining that the power spectral density corresponds to a particular modeled power spectral density of the one or more modeled power spectral densities; and
determining, based on the particular modeled power spectral density, an estimated source that generated the electromagnetic signal.

8. The method as recited in claim 7, wherein the power spectral density corresponds to one or more values that indicate a relative strength for corresponding portions of the electromagnetic spectrum of the electromagnetic signal.

9. The method as recited in claim 5, further comprising:
determining, a first phase of the electric field portion of the electromagnetic signal;
determining, a second phase of a first magnetic field portion of the electromagnetic signal;
determining, a third phase of a second magnetic field portion of the electromagnetic signal; and
determining, based on the first phase, the second phase, and the third phase, a bearing to the source of the electromagnetic signal.

10. The method as recited in claim 5, wherein determining the estimated distance is further based at least in part on at least one of:
a phase variance between the electric field portion of the electromagnetic signal and the magnetic field portion of the electromagnetic signal; and
an amplitude variance between the electric field portion of the electromagnetic signal and the magnetic field portion of the electromagnetic signal.

11. The method as recited in claim 10, wherein determining the estimated distance comprises:
assigning at least a first weight to the correspondence between the detected dispersion pattern and the particular modeled dispersion pattern, the first weight indicating a first confidence level that the correspondence is indicative of the distance to the source of the electromagnetic signal;
assigning at least a second weight to at least one of the phase variance and the amplitude variance, the second weight indicating a second confidence level that the phase and amplitude variance is indicative of the distance to the source of the electromagnetic signal; and
determining the estimated distance based at least in part on the first weight and the second weight.

12. The method as recited in claim 5, further comprising determining a source type of the electromagnetic signal based at least in part on one or more of:
a signal duration associated with the electromagnetic signal;
a symmetry of the electromagnetic signal;
one or more phases associated with the electromagnetic signal;
arrival polarization of the electromagnetic signal;
component frequencies of the electromagnetic signal;
a dominant frequency determined as by a Fourier Analysis of the electromagnetic signal;
the relative amplitudes of the magnetic and electric fields;
a first correlation of the electric field portion to the magnetic field portions of the electromagnetic signal; and
a second correlation between two or more magnetic field portions of the electromagnetic signal.

13. The method as recited in claim 5, further comprising determining the one or more modeled dispersion patterns based at least in part on previously observed electromagnetic signals associated with lightning events that occurred at known distances.

14. A system comprising:
one or more processors;
memory; and
one or more computer-executable instructions that are stored in the memory and that are executable by the one or more processors to perform operations comprising:
detecting an electromagnetic signal;
determining a phase variance between an electric field portion of the electromagnetic signal and a magnetic field portion of the electromagnetic signal; and
determining, based on the phase variance, an estimated distance to a source of the electromagnetic signal.

15. The system as recited in claim 14, wherein the system further comprises an electromagnetic signal detection unit that comprises at least a vertical antenna configured to detect local electric fields, and at least two loop antennae configured to detect local magnetic fields.

16. The system as recited in claim 15, wherein the electromagnetic signal is detected by the electromagnetic signal detection unit.

17. The system as recited in claim 14, the operations further comprising:
determining a power spectral density associated with the electromagnetic signal;
comparing the power spectral density to one or more modeled power spectral densities, wherein individual modeled power spectral densities correspond to a particular power spectral densities that a modeled electromagnetic signal would be expected to exhibit if it was generated by a particular source; and
determining that the power spectral density corresponds to a particular modeled power spectral density of the one or more modeled power spectral densities; and
determining, based on the particular modeled power spectral density, an estimated source that generated the electromagnetic signal.

18. The system as recited in claim 14, the operations further comprising:
determining, a first phase of the electric field portion of the electromagnetic signal;
determining, a second phase of a first magnetic field portion of the electromagnetic signal;
determining, a third phase of a second magnetic field portion of the electromagnetic signal; and
determining, based on the first phase, the second phase, and the third phase, a bearing to the source of the electromagnetic signal.

19. The system as recited in claim 14, the operations further comprising:
detecting a dispersion pattern exhibited by the electromagnetic signal;
comparing the detected dispersion pattern to one or more modeled dispersion patterns, wherein individual modeled dispersion patterns correspond to a particular dispersion pattern that a modeled electromagnetic signal would be expected to exhibit after traveling a particular distance;
determining that the detected dispersion pattern corresponds to a particular modeled dispersion pattern of the one or more modeled dispersion patterns; and
determining, based on the particular modeled dispersion pattern, an estimated distance to a source of the electromagnetic signal.

20. The system as recited in claim 19, the operations further comprising:
determining the one or more modeled dispersion patterns based at least in part on previously observed electromagnetic signals associated with lightning events that occurred at known distances.
